(19) United States
(12) Patent Application Publication
(10) Pub. No.: US 2006/0145314 A1
(43) Pub. Date: Jul. 6, 2006

(54) Tape for tape carrier package

(75) Inventors: Hung-Che Shen, Kaohsiung City (TW); Hung-Hsin Liu, Tainan City (TW); Geng-Shin Shen, Tainan City (TW)

Correspondence Address: THE LAW OFFICES OF ANDREW D. FORTNEY, PH.D., P.C., 7257 N. MAPLE AVENUE, BLDG. D, SUITE 107, FRESNO, CA, 93720, US

(73) Assignees: ChipMos Technologies Inc.; ChipMos Technologies (Bermuda) LTD

(21) Appl. No.: 11/202,898

(22) Filed: Aug. 12, 2005

(30) Foreign Application Priority Data
Dec. 30, 2004 (TW) 093141417

(51) Int. Cl. H01L 23/495

(52) U.S. Cl. 257/668

(57) ABSTRACT

The invention provides a tape for a tape carrier package. The tape includes a flexible insulating film. The flexible insulating film is divided into a plurality of units arranged successively, and each of the units has a device hole and a plurality of leads. The plurality of leads are formed on the flexible insulating film and protrude to the device hole. The device hole has a plurality of corners formed in a form of a notch for preventing the stress from concentrating on and breaking the leads.

### BACKGROUND OF THE INVENTION

1. Field of the Invention

The present invention relates to a circuit tape for packaging, and more particularly, the invention relates to a tape for a tape carrier package.

2. Description of the Prior Art

In the field of integrated circuit chip packaging, tape carrier package (TCP) is one of the common methods. It employs a flexible tape with a device hole and a plurality leads as the chip substrate, and it is the most widely utilized as carrier packages for a semiconductor device for driving a liquid crystal display panel.

Referring to FIG. 1 and FIG. 2, FIG. 1 is a cross-sectional view showing the configuration of a conventional tape carrier package, and FIG. 2 is a top view schematic diagram illustrating the configuration of the conventional tape carrier package. As shown in FIG. 1, a conventional TCP structure 2 includes a semiconductor die 10, a tape 20, and a resin 14. The semiconductor die 10 has a plurality of bumps 12 thereon. The tape 20 has a plurality of leads 21 and a device hole 22. The leads 21 protrude to the device hole 22 and electrically connect to the bumps 12 of the semiconductor die 10. The resin 14 covers the semiconductor die 10 and the leads 21.

However, as shown in FIG. 2, each of the corners 23 of the device hole 22 on the tape 20 is designed as a fillet, so the stress is easily concentrated at the corners 23. Therefore, the leads 21 are easily broken in the packaging process because of the effect of high temperature and pressure. Besides, the tape 20 has lower flexibility because of this design of the corners 23.

Accordingly, the present invention provides a tape for a tape carrier package that solves the problems mentioned above.

### SUMMARY OF THE INVENTION

For achieving the objective and for solving the defects discussed above, the invention provides a tape for a tape carrier package.

According to a first preferred embodiment of the present invention, the tape of the tape carrier package includes a flexible insulating film. The flexible insulating film is divided into a plurality of units arranged successively, and each of the units has a device hole and a plurality of leads. The device hole has a plurality of corners formed in a form of a notch. The leads are formed on the flexible insulating film and protrude to the device hole.

A tape carrier package (TCP) structure, according to a preferred embodiment of the invention, includes a tape and a semiconductor die. The tape includes a flexible insulating film and a plurality of leads. The flexible insulating film has a device hole thereon, and the device hole has a plurality of corners formed in a form of a notch. The leads are formed on the flexible insulating film and protrude to the device hole. The semiconductor die has an active surface and a plurality of bumps, formed on the active surface; each of the bumps connects to one of the leads.

The tape of the tape carrier package of the invention improves the shape of the corners, so as to reduce the stress caused by the temperature change during the packaging process. Meanwhile, the improvement of the shape of the corners also increases the flexibility of the tape, disperses the concentration of the stress, and lowers the stress concentration factor at the corners to reduce the possibility of breaking the leads and to increase the reliability of the tape carrier package.

The advantage and spirit of the invention may be understood by the following recitations together with the appended drawings.

### BRIEF DESCRIPTION OF THE APPENDED DRAWINGS

FIG. 1 is a cross-sectional view showing the configuration of a conventional tape carrier package.

FIG. 2 is a top view schematic diagram illustrating the configuration of the conventional tape carrier package FIG. 3 is a schematic diagram illustrating a tape carrier package structure according to a first preferred embodiment of the invention.

FIG. 4 is a schematic diagram illustrating a tape carrier package structure according to a second preferred embodiment of the invention.

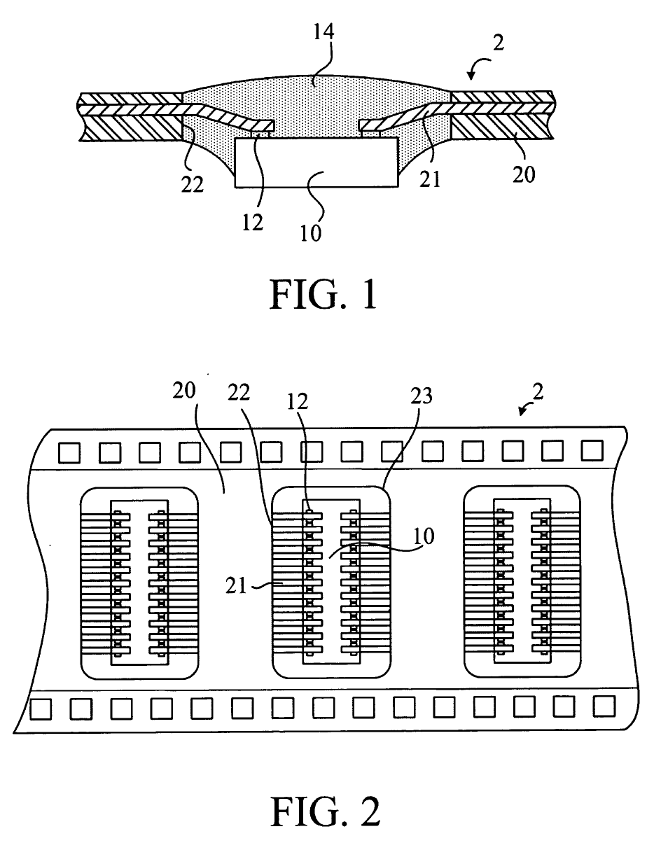

### DETAILED DESCRIPTION OF THE INVENTION

The invention provides a tape for a tape carrier package. According to a preferred embodiment of the invention, the tape includes a flexible insulating film. The flexible insulating film is divided into a plurality of units arranged successively, and each of the units has a device hole and a plurality of leads. The device hole has a plurality of corners formed in a form of a notch. The leads are formed on the flexible insulating film and protrude to the device hole.

Please refer to FIG. 3; FIG. 3 is a schematic diagram illustrating a tape carrier package structure according to a first preferred embodiment of the invention. As shown in FIG. 3, the tape carrier package structure 3 includes a tape 30 and a semiconductor die 10.

The tape 30 is divided into a plurality of units arranged successively, and each of the units has a flexible insulating film 32 and a plurality of leads 34. The flexible insulating film 32 is made of polyimide, polyester or the like and has flexibility. The flexible insulating film 32 has a device hole 38 passing vertically through the flexible insulating film 32 of the tape 30. The device hole 38 is substantially rectangular and has four corners 31 formed in a form of a notch. A plurality of equidistant sprocket holes 33 are formed on the two sides of the flexible insulating film 32 for transportation and orientation. The leads 34 are strip-shaped and protrude to the device hole 38 for connecting with the semiconductor die 10. In the embodiment, the notch is substantially oblong. The semiconductor die 10 has an active surface and a plurality of bumps 12, formed on the active surface; each of the bumps 12 connects to one of the leads 34.

In the practical packaging process, the tape 30 has to go through packaging steps with different temperatures. First, an inner lead bonding (ILB) process is performed on the tape carrier package, in which the bumps 12 of the semiconductor die 10 are connected to the leads 34 in a high temperature machine. The temperature is then lowered to perform a potting step, and the adhesive is then cured at a high temperature. Because the device hole 38 of the tape 30 has the corners 31 in the form of the notch, contractions caused by the temperature can be lessened, and the stress concentration factor at the corners can also be reduced, so as to reduce the possibility of the breaking of the leads 34. Besides, the corners 31 in the form of the notch can also raise the flexibility of the tape.

In an embodiment, the tape carrier package structure further includes a resin coated thereon, so as to cover the leads and the bumps of the semiconductor die.

In an embodiment, the tape carrier package structure further includes a protection layer covering the portions of the leads disposed on the flexible insulating film.

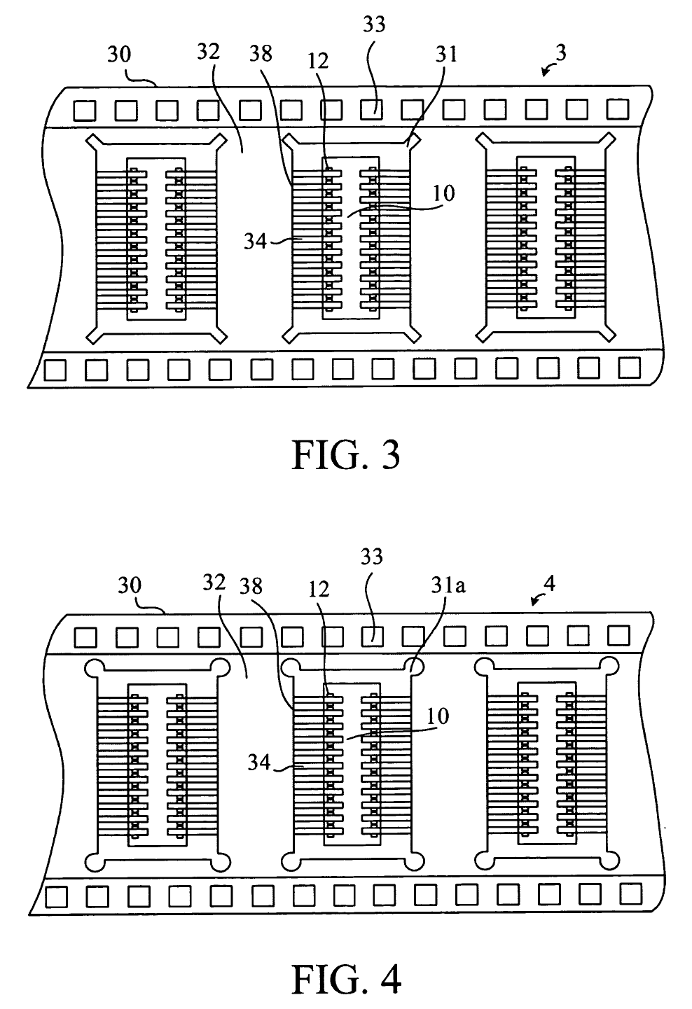

Please refer to FIG. 4; FIG. 4 is a schematic diagram illustrating a tape carrier package structure according to a second preferred embodiment of the invention. As shown in FIG. 4, the tape carrier package structure 4, according to the second preferred embodiment of the invention, includes a tape 30 and a semiconductor die 10. The tape 30 has a flexible insulating film 32 and a plurality of leads 34. The flexible insulating film 32 has flexibility and has a device hole 38 thereon. The leads 34 protrude to the device hole 38 for connecting with the semiconductor die 10. The device hole 38 is substantially rectangular and has four corners 31 formed in a form of a notch. In the embodiment, the notch is substantially arcuate.

With the example and explanations above, the features and spirits of the invention will be hopefully well described. Those skilled in the art will readily observe that numerous modifications and alterations of the device may be made while retaining the teaching of the invention. Accordingly, the above disclosure should be construed as limited only by the metes and bounds of the appended claims.

What is claimed is:

1. A tape for a tape carrier package (TCP), the tape comprising:
a flexible insulating film divided into a plurality of units arranged successively, each of the units having:
a device hole having a plurality of corners formed in a form of a notch; and
a plurality of leads being formed on the flexible insulating film and protruding to the device hole.

2. The tape of claim 1, wherein the leads are strip-shaped.

3. The tape of claim 1, wherein the notch is substantially oblong.

4. The tape of claim 1, wherein the notch is substantially arcuate.

5. The tape of claim 1, wherein each of the units also has a plurality of sprocket holes formed on two sides thereof.

6. The tape of claim 1, wherein the device hole of each unit substantially exhibits a rectangular shape and has four corners.

7. The tape of claim 1, wherein the portions of the leads disposed on the flexible insulating film are covered by a protection layer.

8. A tape carrier package (TCP) structure, comprising:
a tape, comprising:
a flexible insulating film having a device hole thereon, the device hole having a plurality of corners formed in a form of a notch; and
a plurality of leads being formed on the flexible insulating film and protruding to the device hole; and
a semiconductor die having an active surface and a plurality of bumps, formed on the active surface, which each connects to one of the leads.

9. The tape carrier package structure of claim 8, further comprising a resin coated, so as to cover the leads and the bumps.

10. The tape carrier package structure of claim 8, wherein the leads are strip-shaped.

11. The tape carrier package structure of claim 8, wherein the notch is substantially oblong.

12. The tape carrier package structure of claim 8, wherein the notch is substantially arcuate.

13. The tape carrier package structure of claim 8, wherein the flexible insulating film also has a plurality of sprocket holes formed on the two sides thereof.

14. The tape carrier package structure of claim 8, wherein the device hole substantially exhibits a rectangular shape and has four corners.

15. The tape carrier package structure of claim 8, further comprising a protection layer covering the portions of the leads disposed on the flexible insulating film.
